(19) United States
(12) Patent Application Publication
(10) Pub. No.: US 2022/0206118 A1
(43) Pub. Date: Jun. 30, 2022

(54) METHODS AND APPARATUSES FOR THERMAL MANAGEMENT OF A DETECTION SENSOR ASSEMBLY IN A LiDAR SYSTEM

(71) Applicant: Beijing Voyager Technology Co., Ltd., Beijing (CN)

(72) Inventors: Anan Pan, Mountain View, CA (US); Youmin Wang, Mountain View, CA (US); Yufeng Hou, Mountain View, CA (US); Henghui Jiang, Mountain View, CA (US); Yue Lu, Mountain View, CA (US)

(21) Appl. No.: 17/135,880

(22) Filed: Dec. 28, 2020

(51) Int. Cl. G01S 7/481; G01S 17/931; H01S 3/04

(52) U.S. Cl. CPC G01S 7/4813; H01S 3/0405; H01S 3/0401; G01S 17/931

(57) ABSTRACT

A detection module may be optically aligned with an optical lens assembly in a LiDAR system with a thermal management block. The thermal management block may be movably coupled to the chassis with a first screw. The detection module may be optically aligned relative to the optical lens assembly so that a laser beam emitted from a laser module is oriented with an optical path in the optical lens assembly to the detection module. The thermal management block may be translated to be adjacent to the detection module and the first screw may be tightened to fixedly couple the thermal management block to the chassis. Adhesive may be applied and cured between the thermal management block and the detection module to fixedly couple the detection module to the chassis. Thermal gel may be applied between the thermal management block and the detection module in order to form a thermal bridge.

### BACKGROUND

Modern vehicles are often equipped with sensors designed to detect objects and landscape features around the vehicle in real-time to enable technologies such as lane change assistance, collision avoidance, and autonomous driving. A commonly used sensor is a light detection and ranging (LiDAR) system.

A LiDAR system may include a light source, also referred to as a transmission module (TX module), and a light detection system, also referred to as a detection module (also referred to as a receiver (RX) module), to estimate distances to environmental features (e.g., pedestrians, vehicles, structures, plants, etc.). The emitted laser beam from the TX module is used to illuminate a target and the RX module receives the reflections from the laser beam in order for the LiDAR system to measure the time it takes for the transmitted laser beam to arrive at the target and then return to the detection module. In some LiDAR systems, the laser beam may be steered across a region of interest according to a scanning pattern to generate a “point cloud” that includes a collection of data points corresponding to target points in the region of interest. The data points in the point cloud may be dynamically and continuously updated, and may be used to estimate, for example, a distance, dimension, and location of an object relative to the LiDAR system, often with very high fidelity (e.g., within about 5 cm) due to the precision of the optical alignment of the components.

### BRIEF SUMMARY

In some embodiments, the present technology relates to a method of optically aligning a detection module with an optical lens assembly in a LiDAR system with the optical lens assembly coupled to a chassis. The method may comprise movably coupling a thermal management block to the chassis with a first screw coupled to the chassis. With the thermal management bloc coupled to chassis, the thermal management block the detection module may be oriented relative to the optical lens assembly to an optically aligned orientation wherein a path of a laser beam emitted from a laser module is oriented with an optical path in the optical lens assembly to a detection sensor of the detection module. With the detection module oriented, the thermal management block may be translated to be adjacent to the oriented detection module and the first screw may be tightened in order to fixedly couple the thermal management block to the chassis. With the thermal management block fixedly coupled to the chassis, a first portion of adhesive may be applied and cured between the thermal management block and the detection module, and a first portion of thermal gel may be applied between the thermal management block and the detection module.

In some embodiments, the thermal management block may include a body defining a first elongated slot and a second elongated slot, wherein movably coupling the thermal management block to the chassis with the first screw comprises positioning the first screw within the first elongated slot. In some embodiments, the method may include movably coupling the thermal management block to the chassis with a second screw positioned in the second elongated slot and coupled to the chassis, and tightening the second screw and the first screw to fixedly couple the thermal management block to the chassis.

In some embodiments, the detection module incudes a detection circuit board assembly, comprising a board and the detection sensor, and a thermal management bracket. The thermal management bracket may include a metal body. The detection circuit board assembly may be fixedly coupled to the thermal management bracket with screws.

In some embodiments, applying the first portion of adhesive between the thermal management block and detection module may include applying the first portion of adhesive between the thermal management block and the thermal management bracket. In some embodiments, curing the first portion of adhesive fixedly couples the thermal management bracket to the thermal management block.

In some embodiments, the thermal management bracket metal body may include a planar portion defining two notches. The thermal management block may include two tabs extending away from the body. Translating the thermal management block adjacent to the detection module may include positioning the two tabs within the two notches. Applying the first portion of adhesive between the thermal management block and the detection module may include applying the first portion of adhesive between a first notch, of the two notches, and a first tab, of the two tabs.

In some embodiments, the thermal management bracket may include a plurality of mounting posts extending away from the planar portion of the metal body, and the board may be fixedly coupled to the plurality of mounting posts with screws. The board may define a plurality of mountings holes each with a copper trace surrounding the respective mounting hole. The board may be fixedly coupled to the plurality of mounting posts with the screws extending through the mounting holes of the board and the copper traces contacting mounting surfaces of the mounting posts. The thermal management block may include one or more shelves, wherein each of the one or more shelves includes a horizontal surface and a vertical surface. Applying the first portion of thermal gel may include applying the first portion of thermal gel onto the planar portion of the thermal management bracket and the horizontal and vertical surfaces of the one or more shelves in order to form a thermal bridge between the detection module and the thermal management block. In some embodiments, the one or more shelves may include a first shelf, a second shelf and a third shelf. The first shelf may be on a first side of the two elongated slots, the second shelf may be on a second side of the two elongated slots, opposite the first side, and the third shelf may be between the two elongated slots.

In some embodiments, the thermal management block may include a first wing extending from a first side of the body of the thermal management block and a second wing extending from a second side of the body of the thermal management block, in order to define a length of the thermal management block. The length of the thermal management block may correspond to a length of the thermal management bracket so that that thermal energy is transferred from the thermal management bracket to the thermal management block across the respective lengths.

In some embodiments, the present technology relates to a receiver module system of a LiDAR system. The receiver module system may include a chassis, an optical lens assembly coupled to a chassis, a thermal management block coupled to the chassis with a first screw, a detection module optically aligned relative to the optical lens assembly wherein a path of a laser beam emitted from a laser module is oriented with an optical path in the optical lens assembly to a detection sensor of the detection module, adhesive directly fixedly coupling the detection module to the thermal management block in order to be fixedly couple the detection module relative to the chassis, and thermal gel forming a thermal bridge between the detection module and the thermal management block.

In some embodiments, the thermal management block includes a body defining a first elongated slot and a second elongated slot. The first screw may extend through the first elongated slot into the chassis. The thermal management block may be further coupled to the chassis with a second screw extending through the second elongated slot into the chassis. The detection module may include a detection circuit board assembly including a board and the detection sensor, and a thermal management bracket. The thermal management bracket may include a metal body. The detection circuit board assembly may be fixedly coupled to the thermal management bracket with screws. The adhesive may couple the thermal management block to the thermal management bracket. The thermal management bracket metal body may include a planar portion defining two notches. The thermal management block may include two tabs extending away from the body. The two tabs may be positioned within the two notches without contacting the planar portion. The adhesive may be positioned between the two notches and the two tabs.

In some embodiments, the thermal management bracket includes a plurality of mounting posts extending away from the planar portion of the metal body. The board may be fixedly coupled to the plurality of mounting posts with screws. The board may define a plurality of mountings holes each with a copper trace surrounding the respective mounting hole, and the board may be fixedly coupled to the plurality of mounting posts with the screws extending through the mounting holes of the board and the copper traces contacting mounting surfaces of the mounting posts. The thermal management block may include one or more shelves, wherein each of the one or more shelves comprises a horizontal surface and a vertical surface. The thermal gel may be retained between the planar portion of the thermal management bracket and the horizontal and vertical surfaces of the one or more shelves in order to form a thermal bridge between the detection module and the thermal management block. The one or more shelves may include a first shelf, a second shelf and a third shelf. The first shelf may be on a first side of the two elongated slots, the second shelf may be on a second side of the two elongated slots, opposite the first side, and the third shelf may be between the two elongated slots.

In some embodiments, the thermal management block may include a first wing extending from a first side of the body of the thermal management block and a second wing extending from a second side of the body of the thermal management block, in order to define a length of the thermal management block. The thermal management block may correspond to a length of the thermal management bracket and be configured so that that thermal energy is transferred from the thermal management bracket to the thermal management block across the respective lengths.

### BRIEF DESCRIPTION OF THE DRAWINGS

The features of the various embodiments described above, as well as other features and advantages of certain embodiments of the present invention will be more apparent from the following detailed description taken in conjunction with the accompanying drawings, in which:

FIGS. 1A and 1B show a module of an autonomous vehicle LiDAR assembly including a chassis, a detection module, and a thermal management block, according to certain embodiments;

FIG. 2A shows a detection circuit board assembly, according to certain embodiments;

FIG. 2B shows a detection circuit board assembly, according to certain embodiments;

FIGS. 2C and 2D show temperature distributions in a detection circuit board assembly of a detection module, according to certain embodiments;

FIGS. 3A-3D show a thermal management bracket of a detection module, according to certain embodiments;

FIGS. 4A-4D show a thermal management block, according to certain embodiments; and

FIGS. 5A-5G; show steps of optically aligning, fixedly coupling, and thermally coupling a detection module to a chassis using thermal management blocks, according to certain embodiments.

Throughout the drawings, it should be noted that like reference numbers are typically used to depict the same or similar elements, features, and structures.

### DETAILED DESCRIPTION

Aspects of the present disclosure relate generally to thermal management, optical alignment, and securing of a detection module to a chassis. The detection module is optically aligned relative to an optical lens assembly, which may be shared with a transmission module, and secured to a chassis with a thermal management block. The chassis, detection module, transmission module, and optical lens assembly may be part of a LiDAR assembly, according to certain embodiments.

In the following description, various examples of thermal management and securing techniques for a detection module are described. For purposes of explanation, specific configurations and details are set forth in order to provide a thorough understanding of the embodiments. However, it will be apparent to one skilled in the art that certain embodiments may be practiced or implemented without every detail disclosed. Furthermore, well-known features may be omitted or simplified in order to prevent any obfuscation of the novel features described herein.

The following high-level summary is intended to provide a basic understanding of some of the novel innovations depicted in the figures and presented in the corresponding descriptions provided below.

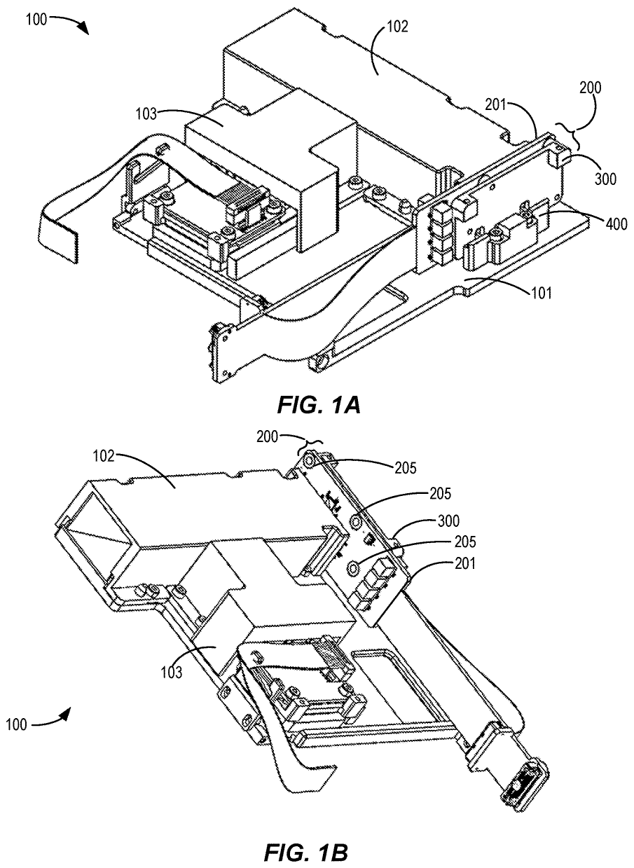

Generally, aspects of the invention are directed to implementations of fixedly coupling a detection module to a chassis so that the detection module is optically aligned with an optical lens assembly, also coupled to the chassis, and so that thermal energy (i.e. heat) generated by circuitry elements of the detection module flows to the chassis in order to dissipate the heat. For example, a Light Detection and Ranging (LiDAR) assembly of an autonomous vehicle may include a receiving module (RX) including a detection module, or a combination transmission and receiving module (TX/RX), including a detection module. The detection module comprises a detection circuit board assembly coupled to a thermal management bracket, for example a shown in FIG. 1A. A laser beam emitted from a transmission module is directed through an optical path of an optical lens assembly, reflected off of an objection and returns through the optical lens assembly to a detection sensor on the detection circuit board assembly. In use, due to a high reverse bias voltage, the detection sensor may generate large amounts of thermal energy. If not dissipated, the thermal energy may reduce the performance of the detection sensor or other components on the detection circuit board assembly. Due to the precision needed for the LiDAR to accurately perform measurements, the disclosed thermal management technology dissipates the thermal energy from the detection circuit board assembly to the chassis in order for the detection module to perform precision measurements for the LiDAR.

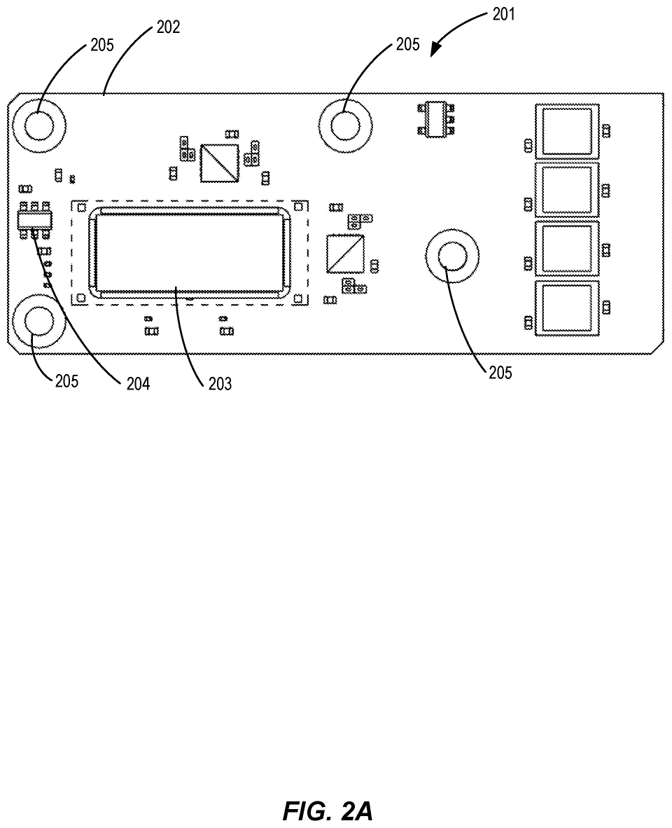

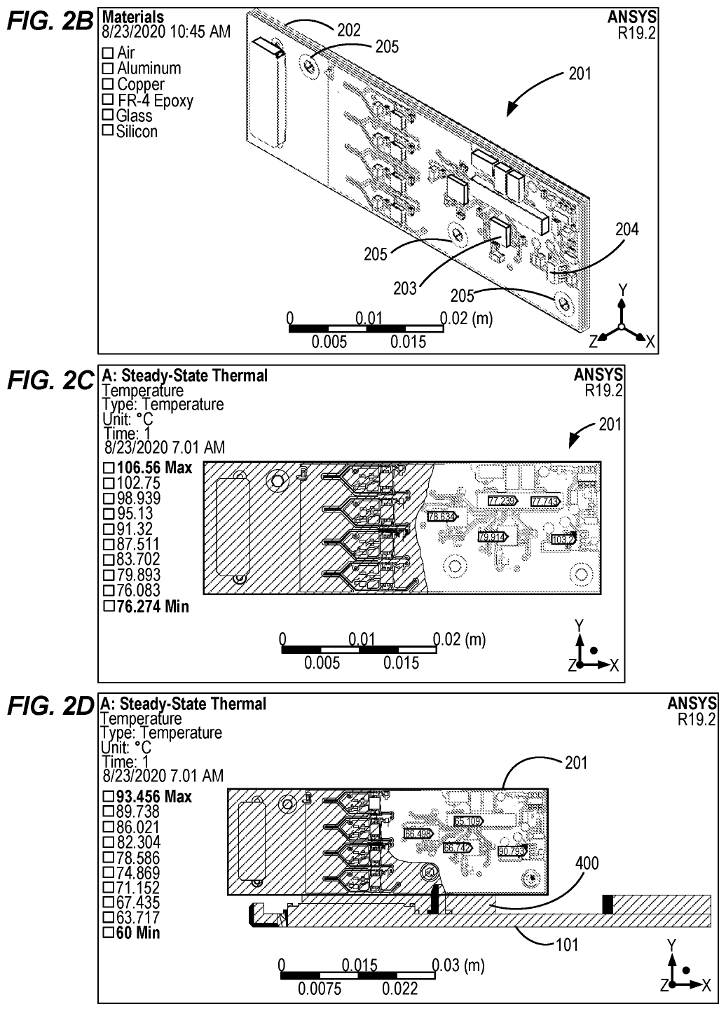

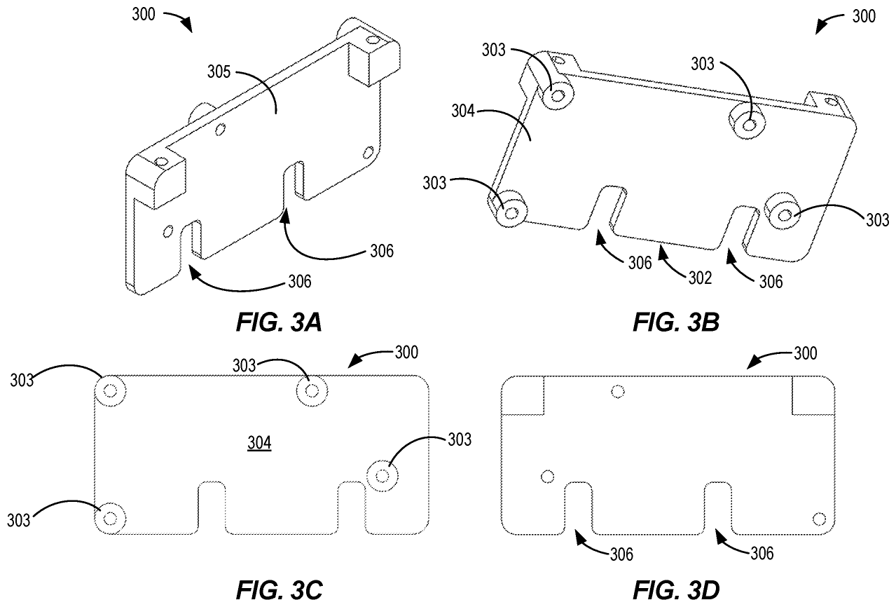

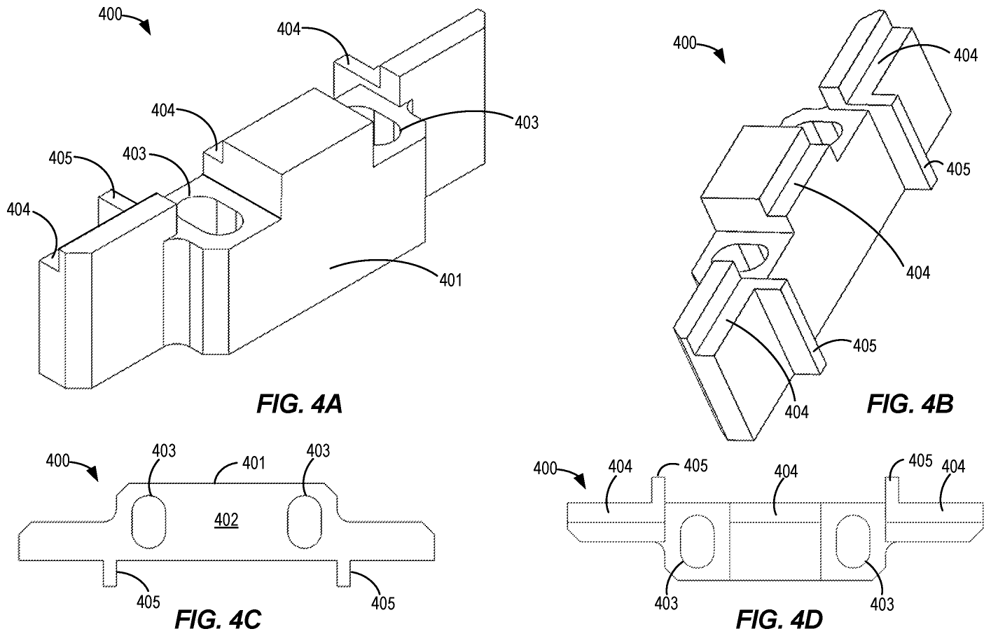

Specifically, the present technology relates to the use of a thermal management bracket, as shown in FIGS. 3A-3D, and a thermal management block, as shown in FIGS. 4A-4D, to dissipate heat from a detection circuit board assembly, as shown in FIG. 2A. The detection circuit board assembly is coupled with screws to a thermal management bracket to form a detection module. The thermal management bracket is fixedly coupled with adhesive and thermally coupled with thermal gel to a thermal management block. The thermal management block is directly coupled to the chassis with screws. The arrangement, shapes, sizes, and materials of the components create an efficient thermal flow path to dissipate thermal energy generated on the detection circuit board assembly. The figures are further described in greater detail below and the scope of the various embodiments of the present invention is not limited by this summary, which merely operates to present a high-level understanding of some of the novel concepts that follow.

FIG. 1A shows a portion of a TX/RX module 100 of an autonomous vehicle LiDAR assembly. As shown, the TX/RX module 100 comprises a chassis 101, a detection module 200, and a thermal management block 400. The detection module 200 comprises a detection circuit board assembly 201, and a thermal management bracket 300. The TX/RX module 100 further comprises an optical lens assembly 102, and a laser/transmission module 103. In use, a laser beam is emitted from the transmission module 103 and directed through an optical path of the optical lens assembly 102, emitted into the surrounding environment from the TX/RX module 100, reflected off of an object in the surrounding environment, returned to the TX/RX module 100 through the optical lens assembly 102 to a detection sensor on the detection circuit board assembly 201. The use of present thermal energy management technology with the TX/RX module 100 as shown is for exemplary purposes, and the thermal energy management technology may be used on other TX/RX modules, RX only modules, or other modules including sensors in a LiDAR system where thermal energy management would enhance performance.

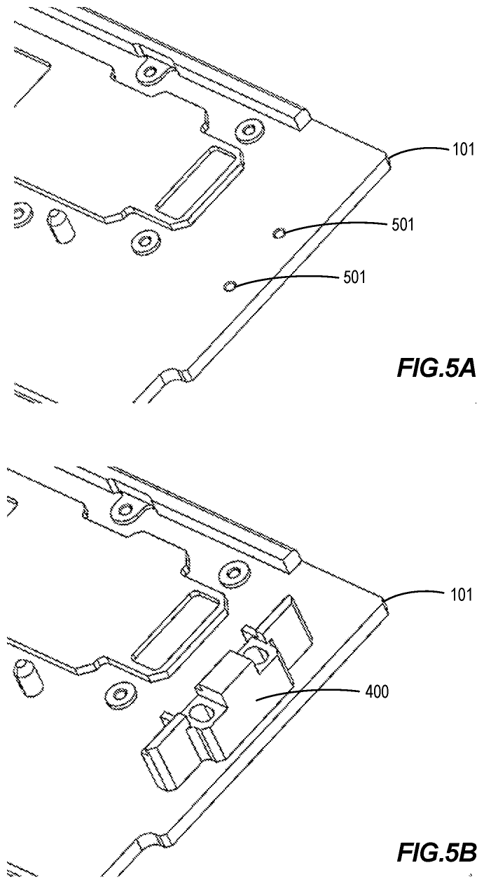

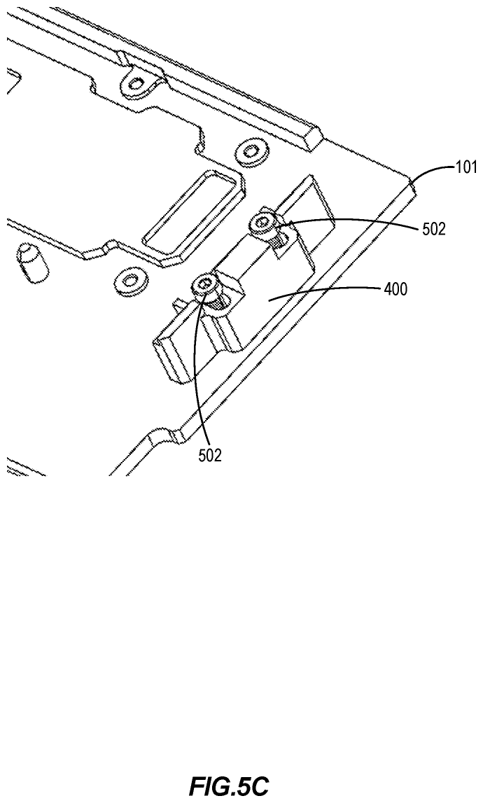

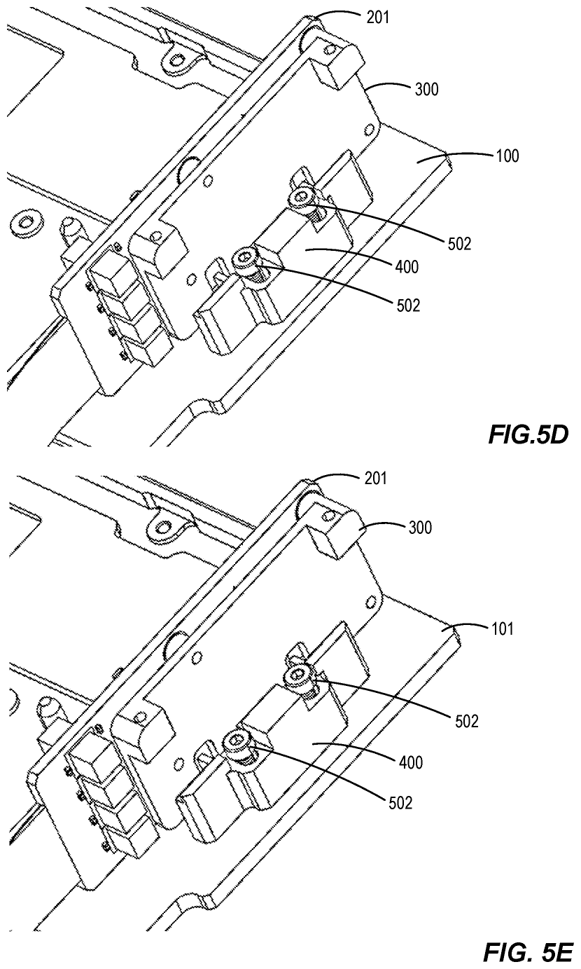

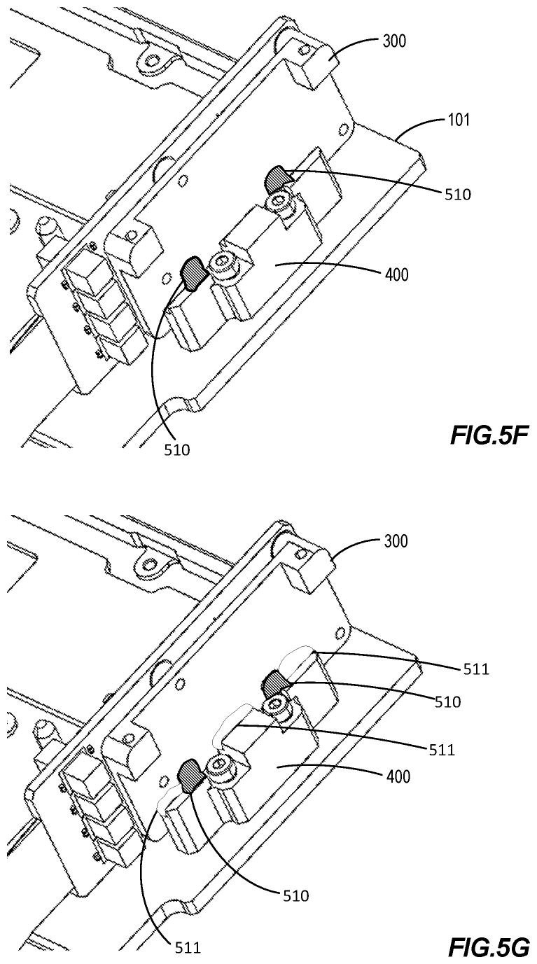

Not shown in FIG. 1A for clarity purposes, but shown in FIGS. 5F and 5G, adhesives 510 and thermal gel 511 may be positioned between the thermal management bracket and the thermal management block to fixedly couple the thermal management block 400 to the thermal management bracket 300.

FIG. 2A shows an embodiment of a detection circuit board assembly 201. As shown the detection circuit board assembly 201 comprises a board 202, for example a printed circuit board (PCB) comprising a plastic reinforced board with conductive traces. The detection circuit board assembly 201 further comprises circuitry components coupled to the board 202, for example a detection sensor 203 and a low drop out regulator 204. In embodiments, the board 202 may be populated with any configuration of circuitry components. In embodiments, the detection sensor 203 comprises one or more Avalanche photodiode arrays (APD arrays). The detection circuit board assembly 201 may comprise wiring/cabling coupled to other components of the TX/RX module 100 for transferring electrical signals to and from the detection circuit board assembly 201 and other components of the LiDAR system.

The board 202 comprises a plurality of mounting holes 205. For example, the board 202 of FIG. 2A comprises four mountings holes. However any number of mounting holes may be present, for example three mounting holes of the board 202 shown in FIG. 2B. In embodiments, the mounting holes 205 may be surrounded by a trace border, for example a copper trace, in order to increase the rate and amount of thermal energy transfer from the board 202 to the thermal management bracket 300 that the board 202 contacts and is coupled to.

One or more of the circuitry components of the detection circuit board assembly may generate thermal energy while in use. For example the detection sensors 203, such as APDs, generate heat due to a high reverse bias voltage. When heat is not dissipated away from the detection circuit board assembly, the excess heat may adversely affect the performance of the detection sensor 203. For example, the increased temperature may increase the thermal noise level of the detection sensor 203. Additionally or alternatively, quantum efficiency of the detection sensor 203 may also be reduced due to increased temperatures. Further, non-uniform heat distribution, with larger temperature differences, across different optical components in the system, may cause alignment issues due to non-uniform thermal expansion. Accordingly, aspects of embodiments of the present technology achieve thermal management of heat generated by the detection circuit board assembly 201 by dissipating the heat to the chassis in order to maintain the performance of the detection sensor 203.

FIG. 2C shows the thermal performance of an embodiment of a detection circuit board assembly 201 without the disclosed thermal management technology, and FIG. 2D shows the thermal performance of an embodiment of a detection circuit board assembly 201 with the disclosed thermal management technology. As shown in FIG. 2C, with no thermal management solution to direct the heat flow onto the mechanical mounting, and little to no convection into the surrounding air, heat generated by the circuitry components, such as the detection sensor 203 and the low drop out regulator 204, significantly increases the temperature of those components as well as disperses heat to other areas on the board 202, compared to FIG. 2D, as evidenced by the larger portion of cooler sections indicated by the diagonal lines in FIG. 2D compared to FIG. 2C, as well as the lower local temperature values in FIG. 2D compared to FIG. 2C. Specifically, as shown, some of the hottest areas in FIG. 2C, e.g. the detection sensor 203 and the low drop out regulator 204, are more than 10 degrees Celsius lower in FIG. 2D than FIG. 2C.

As shown in FIG. 1A, the detection circuit board assembly 201 is coupled to a thermal management bracket 300 to form a detection module 200. FIGS. 3A-3D show an embodiment of a thermal management bracket 300. As shown, the thermal management bracket 300 may be generally planar and rectangular in shape and corresponds to the shape and size of the board 202. The thermal management bracket 300 may also be referred to as a chassis. Accordingly, as used herein, the chassis 101 may be referred to as the chassis or the first chassis, and the thermal management bracket 300 may be referred to as the thermal management chassis or the second chassis. The thermal management bracket 300 may be solid and formed monolithically, for example molded and/or machined from a single piece of material. In embodiments, the thermal management bracket 300 is comprised of a metal with a high thermal conductivity, for example aluminum, copper and/or steel. Solid monolithically formed metal thermal management brackets 300 are advantageous in conducting compared to hollow, webbed, multi-component and/or non-metal constructions.

As shown in FIG. 3B, the thermal management bracket 300 defines a PCB face 302 configured for facing the backside of the board 202. The PCB face 302 comprises a first surface 304 and a plurality of mounting posts 303 extending from the first surface 304. Opposite the first surface 304 is a second surface 305, which in an assembled configuration faces away from the board 202. As shown the first surface 304 is recessed from a mounting surfaces of the mounting posts 303 in order for components on the backside of the board 202 to have clearance from the first surface 304. As shown the mounting posts 303 are generally cylindrical, and may have a diameter corresponding to the trace around the mounting holes 205 on the board 202. The mounting posts 303 define central threaded holes for receiving screws 307 to couple the board 202 of the detection circuit board assembly 201 to the thermal management bracket 300. The contact of the traces around the mounting holes 205 to the end surfaces of the mounting posts 303 and to the screws 307 threaded in the mounting posts 303 provides a thermal bridge between the detection circuit board assembly 201 and the thermal management bracket 300. Thermal energy transferred to the thermal management bracket 300 may spread from the mounting posts 303 around the portion of the thermal management bracket 300 between the surfaces 304 and surface 305.

In embodiments, the thermal management bracket 300 is coupled to the thermal management block 400 with adhesive, and the thermal management block 400 may include features for increasing the adhesive bond strength. For example, as shown in FIGS. 3A-3D, the thermal management bracket 300 defines notches 306 on a bottom edge. As shown, the thermal management bracket 300 comprises two notches 306 used to adhesively couple the thermal management bracket 300 to the thermal management block 400. The notches extend between the first surface 304 and the second surface 305.

As shown in FIG. 1A, the thermal management bracket 300 is positioned adjacent to and coupled to the thermal management block 400. FIGS. 4A-4D show an embodiment of a thermal management block 400. As shown, the thermal management block 400 comprises a central portion 401 having a substantially rectangular prism shape, and end wings 406 extending from opposite sides of the central portion 401 in a direction parallel to al longitudinal axis of the thermal management block 400. The thermal management block 400 defines a bottom surface 402, as shown in FIG. 4C. As shown in FIG. 1A the bottom surface 402 of the thermal management block 400 contacts the chassis 101. The bottom surface 402 is substantially planar covers substantially the entire profile of the thermal management block 400 in order to maximize the size of the thermal bridge between the thermal management block 400 and the chassis 101.

The thermal management block 400 may comprise one or more elongated slots 403, for example two elongated slots 403 as shown in FIGS. 4A-4D, extending through the central portion 401 between a top side and the bottom surface 402. The elongated slots 403 are sized and shaped to receive the screws to secure, as shown for example in FIG. 1A. The elongated slots each comprise a long axis and a short axis, the long axes of each of the elongated slots 403 are parallel to each other and perpendicular to the longitudinal axis of the thermal management block in order to translate in one degree of freedom perpendicular to the longitudinal axis.

The thermal management block 400 further comprises one or more shelves 404. The shelves may be shaped as an upwardly facing horizontal surface, and a vertical surface for facing the detection module 200. The shelves 404 are uses to receive thermal gel and/or adhesive. In embodiments, thermal gel may be a non-setting viscous fluid, and the shelves 404 maintain the thermal gel forming a thermal bridge between the thermal management block 400 and the thermal management bracket 300. As shown in FIG. 4B, a thermal management block 400 may comprise three shelves 404, comprising a first shelf 404 extending from a first end of the thermal management block 400 toward a first of the elongated slots 403, a second shelf 404 between the elongated slots 403, and a third shelf 404 extending from a second end of the thermal management block 400 toward a second of the elongated slots 403. The length of the thermal management block 400 between the first and second ends may correspond to a length of the thermal management bracket 300, which corresponds to a length of the boards 202, so that a thermal gel thermal bridge may extend substantially across the entire width of the thermal management bracket 300 and board 202.

The thermal management block 400 may further comprise tabs 405. As shown in FIG. 1A, the tabs 405 of the thermal management block 400 are received within the notches 306 of the thermal management bracket 300. As shown in FIG. 4B, the tabs 405 may extend from the bottom surface 402 to the horizontal surface of the shelves 404. The tabs 405 may be generally rectangular prisms in shaped.

The thermal management bracket 400 may be solid and formed monolithically, for example molded and/or machined from a single piece of material. In embodiments, the thermal management block 400 is comprised of a metal with a higher thermal conductivity, for example aluminum, copper and/or steel. Solid monolithically formed metal thermal management blocks are advantageous in conducting heat compared to hollow, webbed, multi-component and/or non-metal constructions.

FIGS. 5A-5G show steps of an embodiment of optically aligning, fixedly coupling, and thermally coupling a detection module 200 relative to a chassis 101 of a TX/RX module 100 of a LiDAR assembly. For clarity, other components affixed to the chassis 101, for example as shown in FIG. 1A, are omitted in FIGS. 5A-5G. The other components may be affixed to the chassis 101 before, during and/or after the example steps shown in FIGS. 5A-5G.

As shown in FIG. 5A, the chassis 101 may define a smooth flat surface 509 for receiving the bottom surface 402 of the thermal management block 400. The surface 509 may be larger than the bottom surface 402 of the thermal management block 400 in order to allow for the thermal management block 400 to be positioned at a plurality of locations and orientations. The surface 509 may include holes, for example threaded holes 501, for receiving the screws 502.

As shown in FIG. 5B, the thermal management block 400 may be positioned on the chassis 101 so that the bottom surface 402 contacts surface 509 with the tabs 405 facing toward the portion of the chassis 101 where the optical lens assembly 102 is or will be affixed to the chassis 101, as shown in FIG. 1A.

As shown in FIG. 5C, two screws 502 are inserted into the elongated slots 403, and threaded into holes 501. The two screws 502 are initially not fully tightened so that the thermal management block 400 may be translated in a direction along the long axis of the elongated slots. Specifically, in embodiments, with two screws 502 partially tightened, the thermal management block 400 is able to translate in a single degree of freedom. The two screws 502 extending through the elongated slots 403 prevent rotation of the thermal management block 400 around one of the screws. The thermal management block is able to be positioned at any position between end positions wherein the screws contact opposing ends of the slots in the long axis direction.

As shown in FIG. 5D, the detection module 200 may be positioned over the chassis 101 and optically aligned with the optical lens assembly 102 with the thermal management bracket 300 side facing the thermal management block 400, and the detection circuit board assembly 201 facing the opposite direction toward the optical lens assembly. The detection module 200 may be positioned and aligned using an alignment jig. Positioning and alignment may be performed before, during or after any of the steps shown in FIGS. 5A, 5B and 5C.

To optically align the detection module 200 relative to the optical lens assembly 102, the detection module 200 may be manipulated about one or more of the six degrees of freedom, eg. xyz translation and xyz rotation, and an output beam emitted from the optical lens assembly 102 may be received by the detection sensor 203 to determine that the detection module 200, and therefore detection sensor 203, is in an optically aligned orientation.

With the detection module optically aligned and held in place with an alignment jib, as shown in FIG. 5D, the thermal management block 400, slidably coupled to the chassis 101 with the screws 502, may be translated toward the thermal management bracket 300. As shown the notches 306 and the tabs 405 are sized and positioned so that the tabs are received within the notches with a clearance. The clearance may be about 2 mm. The clearance accounts for manufacturing and assembly tolerances of the components so that tabs may be positioned within the notches without contacting the thermal alignment bracket and causing misalignment.

The thermal management block 400 may be positions so that the shelves 404 contact, or almost contact, the surface 305 of the thermal management bracket, as shown in FIG. 5D. With the thermal management block 400 positioned adjacent the thermal management bracket 300 with the tabs 405 within the notches 306, the screws 502 may be tightened in order to fixedly couple the thermal management block 400 to the chassis 101. The screws 502 are tightened so the bottom surface 402 of the thermal management block 400 is firmly pressed against the surface 509 of the chassis 101 in order to maximize the thermal conduction between the two components. In embodiments, thermal gel may be applied between the surface 509 and the chassis 101.

With the thermal management block 400 fixedly coupled to the chassis 101, and the detection module 200 held in place and optically aligned with the optical lens assembly 102, adhesive may be applied to fixedly couple the thermal management bracket 300 to the thermal management block 400. For example, as shown in FIG. 5F, adhesive 510 may be applied within the notches 306 and around the tabs 405. By applying and curing adhesive between multiple opposing facets, of the tabs and notches, oriented in different directions the bond strength is increased due to forces in any direction being held by the adhesive with a combination of compression, tension and shear. The curing process for the adhesives may be one or more of UV curing, and thermal curing. Examples of adhesive include epoxies, UV glue, hot glue, and instant adhesives.

In embodiments, the adhesive may have a low thermal conductivity and/or the thermal management bracket 300 may not contact the thermal management block 400 resulting in poor conduction of thermal energy from the detection circuit board assembly 201 to the chassis 101. Accordingly, in embodiments, a thermal gel 511 is applied between the thermal management bracket 300 and the thermal management block 400. For example, as shown in FIG. 5G, thermal gel 511 is applied on each of the shelf portions. The vertical and horizontal surfaces of the shelves 404 maintain the thermal gel 511 between the components in order to maintain a high thermal conductivity thermal flow path between the thermal management bracket 300 and the thermal management block 400. In embodiments, the curing of the adhesive may be performed before or after applying the thermal gel. In embodiments, the thermal gel may be applied before, during, and/or after applying the adhesive.

Other variations are within the spirit of the present disclosure. Thus, while the disclosed techniques are susceptible to various modifications and alternative constructions, certain illustrated examples thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims. For instance, any of the examples, alternative examples, etc., and the concepts thereof may be applied to any other examples described and/or within the spirit and scope of the disclosure.

The use of the terms “a” and “an” and “the” and similar referents in the context of describing the disclosed examples (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate examples of the disclosure and does not pose a limitation on the scope of the disclosure unless otherwise claimed. No language in the specification should be construed as indicating any non-claimed element as essential to the practice of the disclosure.

What is claimed is:

1. A method of optically aligning a detection module with an optical lens assembly in a LiDAR system, wherein the optical lens assembly is coupled to a chassis, the method comprising:
movably coupling a thermal management block to the chassis with a first screw coupled to the chassis;
orienting the detection module relative to the optical lens assembly to an optically aligned orientation wherein a path of a laser beam emitted from a laser module is oriented with an optical path in the optical lens assembly to a detection sensor of the detection module;
translating the movably coupled thermal management block adjacent to the oriented detection module and tightening the first screw to fixedly couple the thermal management block to the chassis;
applying a first portion of adhesive between the thermal management block fixedly coupled to the chassis and the oriented detection module;
applying a first portion of thermal gel between the thermal management block fixedly coupled to the chassis and the oriented detection module; and
curing the first portion of adhesive in order to fixedly couple the detection module relative to the chassis.

2. The method of claim 1, wherein the thermal management block comprises a body defining a first elongated slot and a second elongated slot,
wherein movably coupling the thermal management block to the chassis with the first screw comprises positioning the first screw within the first elongated slot, and
wherein the method further comprises:
movably coupling the thermal management block to the chassis with a second screw positioned in the second elongated slot and coupled to the chassis; and
tightening the second screw and the first screw to fixedly couple the thermal management block to the chassis.

3. The method of claim 2, wherein the detection module comprises:
a detection circuit board assembly, comprising a board and the detection sensor; and
a thermal management bracket, comprising a metal body, wherein the detection circuit board assembly is fixedly coupled to the thermal management bracket with screws.

4. The method of claim 3, wherein applying the first portion of adhesive between the thermal management block and detection module comprises applying the first portion of adhesive between the thermal management block and the thermal management bracket, and
wherein curing the first portion of adhesive fixedly couples the thermal management bracket to the thermal management block.

5. The method of claim 4, wherein the thermal management bracket metal body comprises a planar portion defining two notches,
wherein the thermal management block comprises two tabs extending away from the body,
wherein translating the thermal management block adjacent to the detection module comprises positioning the two tabs within the two notches, and
wherein applying the first portion of adhesive between the thermal management block and the detection module comprises applying the first portion of adhesive between a first notch, of the two notches, and a first tab, of the two tabs.

6. The method of claim 5, wherein the thermal management bracket comprises a plurality of mounting posts extending away from the planar portion of the metal body, and
wherein the board is fixedly coupled to the plurality of mounting posts with screws.

7. The method of claim 6, wherein the board defines a plurality of mountings holes each with a copper trace surrounding the respective mounting hole, and
wherein the board is fixedly coupled to the plurality of mounting posts with the screws extending through the mounting holes of the board and the copper traces contacting mounting surfaces of the mounting posts.

8. The method of claim 7, wherein the thermal management block comprises one or more shelves,
wherein each of the one or more shelves comprises a horizontal surface and a vertical surface, and
wherein applying the first portion of thermal gel comprises applying the first portion of thermal gel onto the planar portion of the thermal management bracket and the horizontal and vertical surfaces of the one or more shelves in order to form a thermal bridge between the detection module and the thermal management block.

9. The method of claim 8, wherein the one or more shelves comprise a first shelf, a second shelf and a third shelf, and
wherein the first shelf is on a first side of the two elongated slots, the second shelf is on a second side of the two elongated slots, opposite the first side, and the third shelf is between the two elongated slots.

10. The method of claim 9, wherein the thermal management block comprises a first wing extending from a first side of the body of the thermal management block and a second wing extending from a second side of the body of the thermal management block, in order to define a length of the thermal management block, and
wherein the length of the thermal management block corresponds to a length of the thermal management bracket so that that thermal energy is transferred from the thermal management bracket to the thermal management block across the respective lengths.

11. A receiver module system of a LiDAR system, the receiver module system comprising:
a chassis;
an optical lens assembly coupled to a chassis;
a thermal management block coupled to the chassis with a first screw,
a detection module optically aligned relative to the optical lens assembly wherein a path of a laser beam emitted from a laser module is oriented with an optical path in the optical lens assembly to a detection sensor of the detection module;
adhesive directly fixedly coupling the detection module to the thermal management block in order to be fixedly couple the detection module relative to the chassis, and
thermal gel forming a thermal bridge between the detection module and the thermal management block.

12. The receiver module system claim 11, wherein the thermal management block comprises a body defining a first elongated slot and a second elongated slot,
wherein the first screw extends through the first elongated slot into the chassis,
wherein the thermal management block is further coupled to the chassis with a second screw extending through the second elongated slot into the chassis.

13. The receiver module system of claim 12, wherein the detection module comprises:
a detection circuit board assembly, comprising a board and the detection sensor; and
a thermal management bracket, comprising a metal body, wherein the detection circuit board assembly is fixedly coupled to the thermal management bracket with screws.

14. The receiver module system of claim 13, wherein the adhesive couples the thermal management block to the thermal management bracket.

15. The receiver module system of claim 14, wherein the thermal management bracket metal body comprises a planar portion defining two notches,
wherein the thermal management block comprises two tabs extending away from the body,
wherein the two tabs are positioned within the two notches without contacting the planar portion, and
wherein the adhesive is positioned between the two notches and the two tabs.

16. The receiver module system of claim 15, wherein the thermal management bracket comprises a plurality of mounting posts extending away from the planar portion of the metal body, and
wherein the board is fixedly coupled to the plurality of mounting posts with screws.

17. The receiver module system of claim 16, wherein the board defines a plurality of mountings holes each with a copper trace surrounding the respective mounting hole, and
wherein the board is fixedly coupled to the plurality of mounting posts with the screws extending through the mounting holes of the board and the copper traces contacting mounting surfaces of the mounting posts.

18. The receiver module system of claim 17, wherein the thermal management block comprises one or more shelves,
wherein each of the one or more shelves comprises a horizontal surface and a vertical surface, and
wherein the thermal gel is retained between the planar portion of the thermal management bracket and the horizontal and vertical surfaces of the one or more shelves in order to form a thermal bridge between the detection module and the thermal management block.

19. The receiver module system of claim 18, wherein the one or more shelves comprise a first shelf, a second shelf and a third shelf, and
wherein the first shelf is on a first side of the two elongated slots, the second shelf is on a second side of the two elongated slots, opposite the first side, and the third shelf is between the two elongated slots.

20. The receiver module system of claim 19, wherein the thermal management block comprises a first wing extending from a first side of the body of the thermal management block and a second wing extending from a second side of the body of the thermal management block, in order to define a length of the thermal management block, and
wherein the length of the thermal management block corresponds to a length of the thermal management bracket and is configured so that that thermal energy is transferred from the thermal management bracket to the thermal management block across the respective lengths.
